(19) United States
(12) Patent Application Publication
(10) Pub. No.: US 2009/0173536 A1
(43) Pub. Date: Jul. 9, 2009

(54) Protective Cover for Lamps and Related Structural Unit

(76) Inventor: Adam Kotowicz, Berlin (DE)

Correspondence Address: FRISHAUF, HOLTZ, GOODMAN & CHICK, PC, 220 Fifth Avenue, 16TH Floor, NEW YORK, NY, 10001-7708, US

(21) Appl. No.: 12/228,000

(22) PCT Filed: Jun. 4, 2007
(86) PCT No.: PCT/EP2007/055487

§ 371 Date: Dec. 4, 2008

(30) Foreign Application Priority Data
Jun. 30, 2006 (DE) 10 2006 030 275.3

(51) Int. Cl. H05K 5/00

(52) U.S. Cl. 174/520

(57) ABSTRACT

A protective cover (4) for lamps (1) forms a longitudinal axis (A) and comprises two parts (10, 11), which are in contact with one another transversely to the longitudinal axis. The parts have a goblet-like shape.

### TECHNICAL FIELD

The invention is based on a protective envelope for lamps, in particular with a pressurized fill. Such protective envelopes and lamps with protective envelopes are used for general lighting and especially for photooptical purposes.

### PRIOR ART

Incandescent lamps and primarily high-pressure discharge lamps have, for specific purposes, a fill whose coldfilling pressure is markedly above atmospheric pressure. U.S. Pat. No. 5,140,222 has already disclosed a high-pressure discharge lamp which has a xenon fill. U.S. Pat. No. 6,262,535 has disclosed a high-pressure discharge lamp which has a mercury fill under a very high pressure, the coldfilling pressure being markedly higher than 10 bar.

In the case of such lamps it is advisable to use a protective envelope until the lamps have been installed and are thus protected. Conventional in this case are protective envelopes consisting of polyurethane film which make the transport of the lamps more reliable and safer, but need to be removed before the lamp is installed in the device for space-saving reasons and therefore do not provide complete protection. Protective envelopes consisting of plastic with a structure of two symmetrical half-shells which are intersected parallel to the longitudinal axis of the lamp are also known. In this case, too, there is the same problem of the protective envelope being removed prematurely in order to make it possible to install the lamp.

For pressurized lamps which are filled with xenon or another gas such as argon, longitudinally slotted plastic protective envelopes have until now been used. In a very large number of factories it is not possible to install a lamp with such an envelope in the device. The protective envelope is removed prior to installation of the lamp. Often, protective films are used nowadays in the case of mercury pressurized lamps. Such a protective film is a protective nonwoven which is held at the ends of the lamp with adhesive tapes. Protective nonwovens have the disadvantage of the ingress of dust and the effect of fluff, which is undesirable for the semiconductor industry.

### DESCRIPTION OF THE INVENTION

The object of the present invention is to extend and to improve the protective effect in the case of a protective envelope for lamps of the generic type.

This object is achieved by characterizing features of claim 1. Particularly advantageous configurations are given in the dependent claims.

The invention is based on the concept of protecting technical personnel from a lamp explosion until the lamp is finally installed in the device.

The protective envelope therefore comprises two parts, whose separating line or separating area runs transversely with respect to the lamp axis. Naturally, the separating area can also be stepped. Both parts are preferably approximately symmetrical and each cover approximately half of the lamp.

The protective envelope can be fastened, for example, with screw nuts on the lamp.

For understanding the concept it is helpful to split the lamp in imaginary fashion into a side facing the device, into which the lamp is intended to be installed, and a side facing away therefrom. The device may be, for example, a reflector. Prior to installation of the lamp, the half or part of the envelope which faces the device is removed. In a specific example, this is the “lower” part, which covers that side of the lamp which faces the reflector. As a result of a suitable lamp orientation, for example approximately horizontal, when the lamp is inserted in the reflector, with the unprotected lamp end pointing away from the operating force, the operating force is virtually completely protected during installation since the lamp bulb is still partially enveloped up until final fitting.

The lamp is preferably fitted in the device together with the still fastened second envelope part facing away from the device. Then, the rest of the envelope is also removed.

A suitable material for the protective envelope is in particular plastic or the like. Specifically, in particular polymethylmethacrylate or another crosslinked polymer such as polyurethane is used. Further materials are crosslinked elastomers, crosslinked silicone rubber, but temperature-resistant thermoplastics from the families of polypropylene (PP), polyamide (PA), polyester (PETP, PBTP), polycarbonate (PC) can also be used. Furthermore, particularly thermally stable and flame-retardant halopolymers with low permeation rates for oxygen or water, such as the polar substances polytetrafluoroethylene (PTFE), ethylene chlorotrifluoroethylene (ECTFE), tetrafluoroethylene hexafluoropropylene (FEP), polychlorotrifluoroethylene (PCTFE), polyvinylidene fluoride (PVDF) and polyvinylidene chloride (PVDC), can also be used.

### BRIEF DESCRIPTION OF THE DRAWINGS

The invention will be explained in more detail below with reference to a plurality of exemplary embodiments. In the figures:

FIG. 1 shows a high-pressure discharge lamp with an associated protective envelope;

FIG. 2 shows the removal of a first part of the protective envelope in the case of the lamp shown in FIG. 1;

FIG. 3 shows the installation of the partially protected lamp in a reflector;

FIG. 4 shows the removal of a second part of the protective envelope in the case of the installed lamp;

FIG. 5 shows a further exemplary embodiment of a protective envelope.

### PREFERRED EMBODIMENT OF THE INVENTION

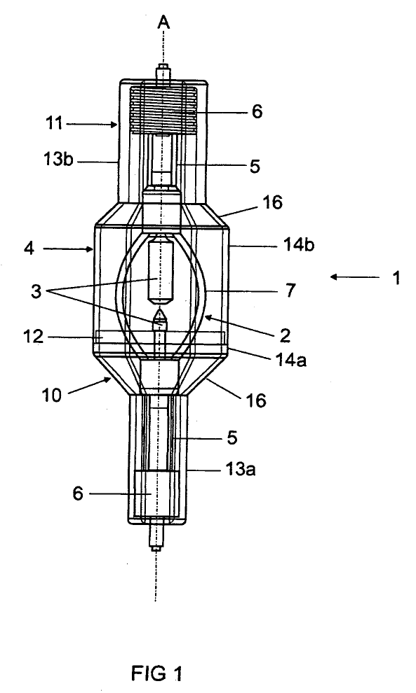

FIG. 1 shows a high-pressure discharge lamp 1, which has a longitudinal axis A. It has a bulb 2, which contains two electrodes 3 and a fill with a given coldfilling pressure. The lamp is completely surrounded by a protective envelope 4, which is likewise oriented on the longitudinal axis A.

The fill has xenon and/or mercury in pressurized form. A coldfilling pressure of several bar, for example 5 bar, is typical. However, the protective envelope can naturally also be used in the case of lamps with no notable excess pressure, the protective envelope then merely acting as protection against electric shock. Another gas such as argon or krypton can of course also be used as the inert gas.

The bulb has a central part 7, which surrounds the discharge volume, and two ends, which are in this case in the form of stems 5, which protrude from the bulb at opposite sides. In each case one base part 6 is fitted on the ends. Preferably, this base part, at least in the case of one base part, is equipped with a screw thread or the like. The base part protrudes laterally over the shaft, which makes it possible to fasten the protective envelope in clamping fashion on the base part.

The protective envelope 4 itself comprises at least two parts 10, 11, the contact zone 12 being positioned between the two parts substantially transversely with respect to the lamp axis A. Each part has a goblet-like shape, a narrow stalk or neck 13a, 13b with a small dimension, in particular with a small diameter, in each case surrounding the stem 5 of the lamp, which may be in the form of a fuse seal or else a pinch seal. Towards the discharge volume, the part widens, for example via a bevel 16, to form a cup 14a, 14b, which is formed by a tubular section with a larger diameter or an angular hollow profile, which is a hexagon or octagon in cross section and has a larger maximum diameter.

Preferably, the length of the cup 14a, 14b is different for both parts. A first part of the protective envelope, which is intended to protect that side of the lamp which faces the device, has a relatively short cup 14a. It covers only a small part of the discharge volume. A second part, which is intended to protect that side of the lamp which faces away from the device, has a comparatively long cup 14b. It covers the majority of the discharge volume.

The second part is fastened on the lamp by virtue of the fact that it bears in clamping fashion against the screw-type base of the lamp. For this purpose, the neck of the second part has precisely an inner diameter which is matched to the screw-type base. Alternatively, the neck even itself has a matching thread, with the result that it can be screwed onto the screw-type base.

The two parts of the protective envelope each have a narrow connecting zone transversely with respect to the lamp axis at their open ends pointing towards one another, in which connecting zone the wall thickness of the protective envelope is reduced such that the two connecting zones can be pushed one over the other. Preferably, the plane of the connecting zones, also referred to as the separating plane, runs between the two parts of the protective envelope in such a way that the cup of one part covers more than 70%, preferably more than 90%, of the length of the central part 7 of the lamp.

The neck of the two parts preferably has a different diameter, which is matched to the respective base part of the embedded lamp in such a way that a clamping effect is produced. The base parts are different because one of the base parts rests in the reflector and the second base part protrudes out of the opening of the reflector.

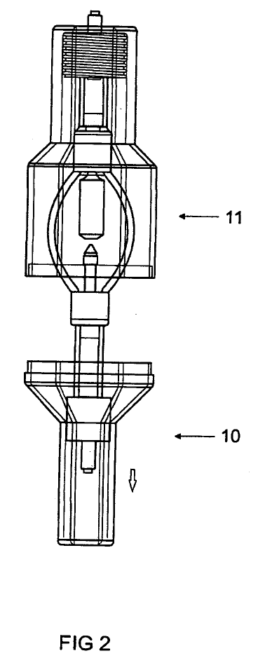

FIG. 2 schematically illustrates the fact that the first part 10 of the protective envelope is drawn away from the lamp (arrow), while the second part 11 still covers the lamp.

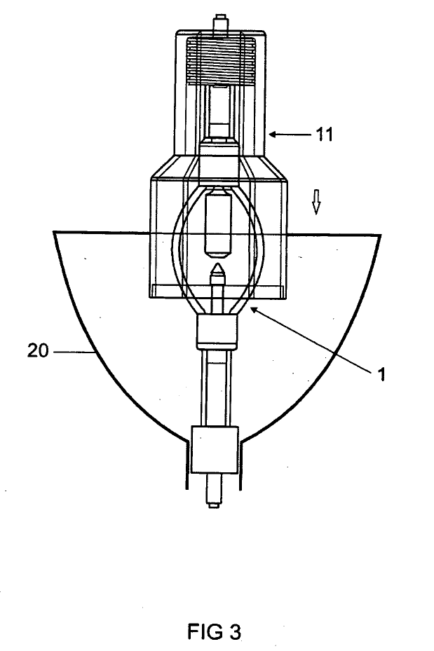

In FIG. 3, this partially protected lamp 1 is installed in a device, namely a reflector 20 (arrow). In the case of an explosion, the operating personnel are now still largely protected by the remaining second part 11 of the protective envelope.

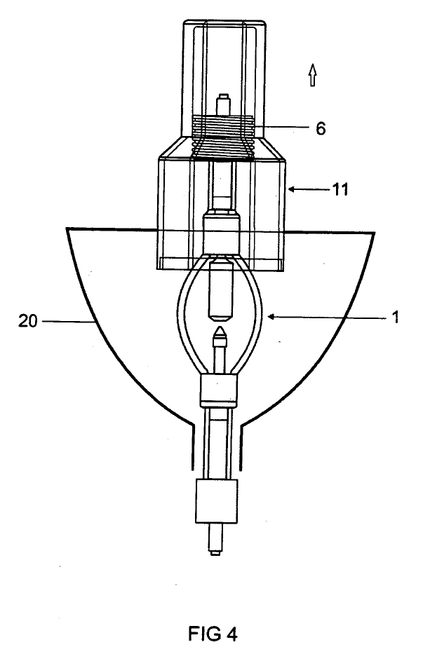

Once the lamp has been installed in the reflector 20 (see FIG. 4), finally the second part of the protective envelope can also be drawn away (arrow) and then the second base part connected to a suitable lampholder in order to bring the lamp into operation. The operating personnel are therefore only subjected to an unprotected lamp for a very short period of time.

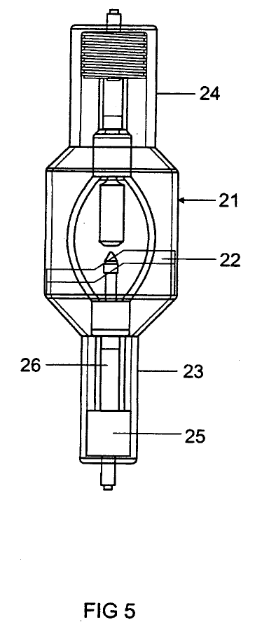

FIG. 5 shows a further exemplary embodiment of a protective envelope 21, in which the connecting zone 22 is not flat, but is stepped. This makes it easier for the two parts 23, 24 of the protective envelope to be joined together. The parts are in this case tubular instead of polygonal.

The use of the protective envelope is always particularly expedient when the coldfilling pressure of the lamp is greater than 1 bar, in particular greater than 2 bar.

A lamp with a single bulb is normally used as the lamp.

It is advantageous if the lamp has, at least on one stem, a base part which provides means for anchoring the protective envelope on the base part. These means are generally a projection protruding transversely with respect to the axis A, as can already be realized in the simplest case by a suitable diameter 25 of the base part which is greater than that of the stem 26.

1. A protective envelope for a lamp which has a longitudinal axis, the protective envelope comprising two parts, characterized in that the separating plane between the two parts runs substantially transversely with respect to the longitudinal axis.

2. The protective envelope as claimed in claim 1, characterized in that the parts have a goblet-like shape with a neck part and a cup part.

3. The protective envelope as claimed in claim 2, characterized in that the neck part has a tubular shape, with a given diameter.

4. The protective envelope as claimed in claim 2, characterized in that the cup part has a tubular shape or a shape which is polygonal in cross section, in particular with a given maximum diameter which is greater than that of the neck part.

5. The protective envelope as claimed in claim 1, characterized in that at least one of the parts has means for fastening to the lamp.

6. A structural unit comprising a lamp with a bulb and a fill therein and a removable protective envelope as claimed in claim 1 surrounding said lamp.

7. The structural unit as claimed in claim 6, characterized in that the lamp has a fill with a coldfilling pressure of more than 1 bar, in particular at least 2 bar.

8. The structural unit as claimed in claim 6, characterized in that the bulb has a central part and two stems, the separating plane between the two parts of the protective envelope running in such a way that the cup of one part covers more than 70%, preferably more than 90% of the length of the central part.

9. The structural unit as claimed in claim 6, characterized in that the lamp has a base part on at least one stem, said base part providing means for anchoring the protective envelope on the base part.
